(19) United States
(12) Patent Application Publication
(10) Pub. No.: US 2012/0199848 A1
(43) Pub. Date: Aug. 9, 2012

(54) SILICON CARBIDE SEMICONDUCTOR DEVICE AND METHOD FOR MANUFACTURING SAME

(75) Inventors: Satomi ITO, Osaka-shi (JP); Shin HARADA, Osaka-shi (JP); Jun GENBA, Osaka-shi (JP); Kazuhiro FUJIKAWA, Osaka-shi (JP)

(73) Assignee: SUMITOMO ELECTRIC INDUSTRIES, LTD., Osaka-shi (JP)

(21) Appl. No.: 13/366,694

(22) Filed: Feb. 6, 2012

Related U.S. Application Data
(60) Provisional application No. 61/440,080, filed on Feb. 7, 2011.

(30) Foreign Application Priority Data
Feb. 7, 2011 (JP) 2011-023677

(51) Int. Cl. H01L 29/16; H01L 21/20

(52) U.S. Cl. 257/77; 438/478; 257/E29.082; 257/E21.09

(57) ABSTRACT

A buffer layer is provided on a substrate, is made of silicon carbide containing an impurity, and has a thickness larger than 1 μm and smaller than 7 μm. A drift layer is provided on the buffer layer and is made of silicon carbide having an impurity concentration smaller than that of the buffer layer. In this way, there can be provided a silicon carbide semiconductor device having the drift layer having a desired impurity concentration and a high crystallinity.

### BACKGROUND OF THE INVENTION

1. Field of the Invention

The present invention relates to a silicon carbide semiconductor device and a method for manufacturing the silicon carbide semiconductor device.

2. Description of the Background Art

In recent rears, a silicon carbide semiconductor device, i.e., a semiconductor device having a semiconductor layer made of silicon carbide has begun to be used. For example, Japanese National Patent Publication No. 2005-508086 (Patent Literature 1) discloses a semiconductor device having a silicon carbide substrate, a buffer layer formed on the silicon carbide substrate, and an N⁻ drift region formed on the buffer layer.

The buffer layer and the drift region (drift layer) are normally deposited while heating the silicon carbide substrate. At an initial stage in which the silicon carbide substrate has started to be heated, the temperature of the silicon carbide substrate is unstable and is likely to be deviated from its desired temperature. In particular, temperature overshoot is likely to take place. When the temperature of the silicon carbide substrate is thus deviated from its desired value, the film to be deposited will have a difference in concentration of conductive impurity. For example, when it is deposited at an excessively high temperature as a result of the temperature overshoot, the impurity concentration thereof is deviated from its desired value.

Meanwhile, if standby time from the start of heating until the start of deposition is made longer, the temperature of the substrate is stabilized and then the deposition is started. However, in this case, a surface of the silicon carbide substrate is heated for a long time to desorb Si atoms from this surface. As a result of the desorption of the Si atoms, the surface becomes rich in C atoms, i.e., is carbonized. On such a surface, a silicon carbide layer having a high crystallinity is hardly epitaxially grown.

As described above, there is a trade-off relation between the stabilization of impurity concentration and the improvement of crystallinity. However, the drift layer is required to have both a desired impurity concentration and a high crystallinity.

### SUMMARY OF THE INVENTION

In view of this, the present invention has its object to provide a silicon carbide semiconductor device including a drift layer having a desired impurity concentration and a high crystallinity, as well as a method for manufacturing such a silicon carbide semiconductor device.

A silicon carbide semiconductor device of the present invention includes a substrate, a buffer layer, and a drift layer. The buffer layer is provided on the substrate, is made of silicon carbide containing an impurity, and has a thickness larger than 1 μm and smaller than 7 μm. The drift layer is provided on the buffer layer and is made of silicon carbide having an impurity concentration smaller than that of the buffer layer.

According to this silicon carbide semiconductor device, the buffer layer has its thickness greater than 1 μm. Hence, as compared with the case where the buffer layer has its thickness equal to or smaller than 1 μm, a longer time elapses from the start of heating of the substrate in depositing the buffer layer. Accordingly, the temperature of the substrate is more stabilized at the time of starting to deposit the drift layer. Because the substrate can attain the temperature with high precision in the step of depositing the buffer layer, the drift layer can be provided with a desired impurity concentration.

Further, during a period of time until the substrate temperature is stabilized, the buffer layer is deposited rather than nothing being performed while waiting for time to pass. Accordingly, while growing the surface of the substrate, one can wait for the substrate temperature to be stabilized. Hence, the surface thereof can be avoided from being carbonized due to desorption of Si atoms unlike the case of just waiting for the temperature to be stabilized. Accordingly, crystallinity is improved in the surface of the buffer layer, which leads to improved crystallinity of the drift layer to be deposited thereon.

Further, the thickness of the buffer layer is smaller than 7 μm. Hence, the time required for the deposition of the buffer layer does not become too long.

Preferably, the buffer layer has an impurity concentration larger than an impurity concentration obtained by multiplying that of the drift layer by 2 and smaller than an impurity concentration obtained by multiplying that of the drift layer by 100. More preferably, the impurity concentration of the buffer layer is smaller than an impurity concentration obtained by multiplying that of the drift layer by 50.

Preferably, the impurity contained in each of the buffer layer and the drift layer includes at least one of aluminum and nitrogen.

Preferably, the buffer layer includes first and second layers. The first layer is provided on the substrate. The second layer is provided on the first layer and has an impurity concentration smaller than that of the first layer and greater than that of the drift layer. More preferably, the impurity concentration of the first layer is greater than 3×10¹⁶ cm⁻³.

It should be noted that the buffer layer may include another layer in addition to the first and second layers. Alternatively, the buffer layer may be constituted by a single layer.

A method for manufacturing a silicon carbide semiconductor device in the present invention includes the following steps.

A substrate starts to be heated. After the substrate starts to be heated, a buffer layer is deposited on the substrate. The buffer layer is made of silicon carbide containing an impurity and having a thickness larger than 1 μm and smaller than 7 μm. On the buffer layer, a drift layer is deposited. The drift layer is made of silicon carbide having an impurity concentration smaller than that of the buffer layer.

According to this manufacturing method, the buffer layer has a thickness greater than 1 μm. Hence, as compared with the case where the buffer layer has a thickness equal to or smaller than 1 μm, a longer time elapses from the start of heating of the substrate in depositing the buffer layer. Accordingly, the temperature of the substrate is more stabilized at the time of starting to deposit the drift layer. Because the substrate can attain the temperature with high precision in the step of depositing the buffer layer, the drift layer can be provided with a desired impurity concentration.

Further, during a period of time until the substrate temperature is stabilized, the buffer layer is deposited rather than nothing being performed while waiting for time to pass. Accordingly, while growing the surface of the substrate, one can wait for the substrate temperature to be stabilized. Hence, the surface thereof can be avoided from being carbonized due to desorption of Si atoms unlike the case of just waiting for the temperature to be stabilized. Accordingly, crystallinity is improved in the surface of the buffer layer, which leads to improved crystallinity of the drift layer to be deposited thereon.

Further, the thickness of the buffer layer is smaller than 7 μm. Hence, the time required for the deposition of the buffer layer does not become too long.

Preferably, throughout both the step of depositing the buffer layer and the step of depositing the drift layer, a setting temperature of the substrate is maintained constant. Accordingly, in the step of depositing the drift layer, the substrate can attain the temperature with improved precision.

Preferably, each of the step of depositing the buffer layer and the step of depositing the drift layer is performed in a chamber by means of a chemical vapor deposition method in which a process gas is supplied onto the substrate. The process gas includes a material gas for forming silicon carbide and an impurity gas for adding an impurity into silicon carbide. The impurity gas includes at least one of trimethylaluminum, nitrogen, and ammonia. In this way, each of the buffer layer and the drift layer can be provided with the conductive impurity.

Preferably, throughout both the step of depositing the buffer layer and the step of depositing the drift layer, a total pressure in the chamber is maintained constant. In this way, the total pressure in the chamber can be stabilized when starting the film formation of the drift layer.

As described above, the present invention provides a silicon carbide semiconductor device including a drift layer having a desired impurity concentration and a high crystallinity.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross sectional view schematically showing a configuration of a silicon carbide semiconductor device in one embodiment of the present invention.

FIG. 2 is a flowchart schematically showing a method for manufacturing the silicon carbide semiconductor device of FIG. 1.

FIG. 3 is a cross sectional view schematically showing a first step of the method for manufacturing the silicon carbide semiconductor device of FIG. 1.

FIG. 4 is a cross sectional view schematically showing a second step of the method for manufacturing the silicon carbide semiconductor device of FIG. 1.

FIG. 5 is a cross sectional view schematically showing a third step of the method for manufacturing the silicon carbide semiconductor device of FIG. 1.

FIG. 6 is a cross sectional view schematically showing a fourth step of the method for manufacturing the silicon carbide semiconductor device of FIG. 1.

FIG. 7 is a cross sectional view schematically showing a fifth step of the method for manufacturing the silicon carbide semiconductor device of FIG. 1.

FIG. 8 is a cross sectional view schematically showing a sixth step of the method for manufacturing the silicon carbide semiconductor device of FIG. 1.

FIG. 9 is a cross sectional view schematically showing a seventh step of the method for manufacturing the silicon carbide semiconductor device of FIG. 1.

FIG. 10 is a cross sectional view schematically showing an eighth step of the method for manufacturing the silicon carbide semiconductor device of FIG. 1.

FIG. 11 is a cross sectional view schematically showing a ninth step of the method for manufacturing the silicon carbide semiconductor device of FIG. 1.

FIG. 12 is a cross sectional view schematically showing a tenth step of the method for manufacturing the silicon carbide semiconductor device of FIG. 1.

FIG. 13 is a graph showing one example of impurity concentration profile of the silicon carbide semiconductor device of FIG. 1.

FIG. 14 is a graph showing one example of impurity concentration profile of a silicon carbide semiconductor device of a comparative example.

FIG. 15 is a graph showing one example of a relation between heating time of the silicon carbide substrate and a temperature of the silicon carbide substrate.

### DESCRIPTION OF THE PREFERRED EMBODIMENTS

The following describes an embodiment of the present invention with reference to figures.

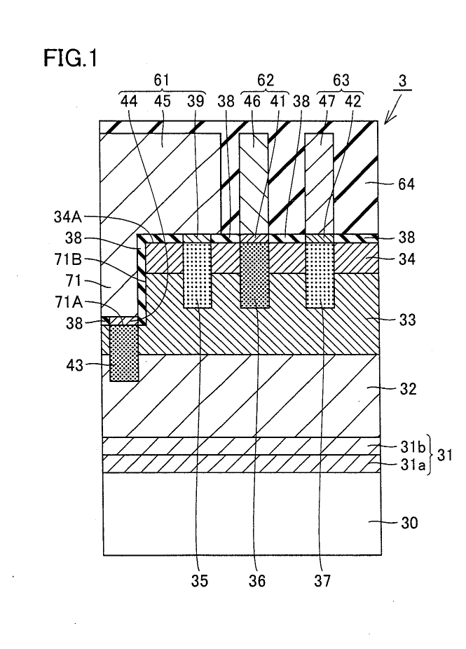

Referring to FIG. 1, a silicon carbide semiconductor device of the present embodiment is a junction field effect transistor (JFET). JFET 3 has a substrate 30, a buffer layer 31, a drift layer 32, an n type layer 33, and a p type layer 34.

Substrate 30 is an n type substrate, and is preferably made of single-crystal silicon carbide. Preferably, the single-crystal silicon carbide has a hexagonal crystal structure.

Buffer layer 31 is a p type semiconductor layer provided on substrate 30. Buffer layer 31 is made of silicon carbide containing aluminum as a conductive impurity. Buffer layer 31 has a thickness larger than 1 μm and smaller than 7 μm. Preferably, buffer layer 31 has a thickness larger than 2 μm.

In the present embodiment, buffer layer 31 includes a first layer 31a and a second layer 31b. First layer 31a is provided on substrate 30. Second layer 31b is provided on first layer 31a, and has an impurity concentration smaller than that of first layer 31a and larger than that of drift layer 32. Preferably, first layer 31a has an impurity concentration greater than 3×10¹⁶ cm⁻³. Further, buffer layer 31 preferably has an impurity concentration larger than an impurity concentration obtained by multiplying that of drift layer 32 by 2 and smaller than an impurity concentration obtained by multiplying that of drift layer 32 by 100. More preferably, buffer layer 31 has an impurity concentration smaller than an impurity concentration obtained by multiplying that of drift layer 32 by 50.

Drift layer 32 is a p type semiconductor layer provided on buffer layer 31. Drift layer 32 is made of silicon carbide containing aluminum as a conductive impurity. Drift layer 32 is made of silicon carbide having an impurity concentration smaller than that of buffer layer 31. Drift layer 32 has a thickness of, for example, 10 μm. Drift layer 32 has an impurity concentration of, for example, 7.5×10¹⁵ cm⁻³.

N type layer 33 is a silicon carbide layer having a thickness of 0.45 μm and having an n type impurity concentration of 2×10¹⁷ cm³, for example. P type layer 34 is a silicon carbide layer having a thickness of 0.25 μm and having a p type impurity concentration of 2×10¹⁷ cm⁻³, for example. In p type layer 34 and n type layer 33, a first n type region 35 and a second n type region 37 are formed, each of which contains an impurity having n type conductivity (n type impurity) at a concentration (for example, approximately 1×10²⁰ cm⁻³) higher than that of n type layer 33. Between first n type region 35 and second n type region 37, a first p type region 36 is formed which contains an impurity having p type conductivity (p type impurity) at a concentration (for example, approximately 1×10¹⁸ cm⁻³) higher than those of drift layer 32 and p type layer 34. Namely, first n type region 35, first p type region 36, and second n type region 37 are formed to reach or come into n type layer 33 through p type layer 34. In addition, each of first n type region 35, first p type region 36, and second n type region 37 has a bottom portion spaced away from the upper surface of drift layer 32 (a boundary portion between drift layer 32 and n type layer 33).

On the side opposite to first p type region 36 when viewed from first n type region 35, a groove portion 71 is formed to extend from an upper surface 34A of p type layer 34 (a main surface opposite to the n type layer 33 side) through p type layer 34 to reach or come into n type layer 33. Namely, a bottom wall 71A of groove portion 71 is located inside n type layer 33, at a distance from an interface between drift layer 32 and n type layer 33. In addition, a second p type region 43 containing a p type impurity at a concentration higher than those in drift layer 32 and p type layer 34 (for example, approximately 1×10¹⁸ cm⁻³) is formed to extend from bottom wall 71A of groove portion 71 through n type layer 33 to reach or come into p type layer 32. A bottom portion of this second p type region 43 is arranged at a distance from an upper surface of buffer layer 31 (a boundary portion between buffer layer 31 and drift layer 32).

In addition, a source contact electrode 39, a gate contact electrode 41, a drain contact electrode 42, and a potential holding contact electrode 44 serving as ohmic contact electrodes are formed in contact with upper surfaces of first n type region 35, first p type region 36, second n type region 37, and second p type region 43, respectively.

An oxide film 38 is formed between each of source contact electrode 39, gate contact electrode 41, drain contact electrode 42, and potential holding contact electrode 44 serving as ohmic contact electrodes and adjacent another ohmic contact electrode. More specifically, oxide film 38 serving as an insulating film is formed on upper surface 34A of p type layer 34 and on bottom wall 71A and a sidewall 71B of groove portion 71, so as to cover the entire region other than regions where source contact electrode 39, gate contact electrode 41, drain contact electrode 42, and potential holding contact electrode 44 are formed. Adjacent ohmic contact electrodes are thus isolated from each other.

Further, a source wire 45, a gate wire 46, and a drain wire 47 are formed to be in contact with the upper surfaces of source contact electrode 39, gate contact electrode 41, and drain contact electrode 42, respectively, and they are electrically connected to the ohmic contact electrodes. Source wire 45 is also in contact with an upper surface of potential holding contact electrode 44, and hence it is also electrically connected to potential holding contact electrode 44. Namely, source wire 45 is formed to extend from the upper surface of source contact electrode 39 to the upper surface of potential holding contact electrode 44, and thus potential holding contact electrode 44 is held at a potential as high as source contact electrode 39. Source wire 45, gate wire 46, and drain wire 47 are made of a conductor such as Al. Source contact electrode 39 and source wire 45 constitute a source electrode 61, gate contact electrode 41 and gate wire 46 constitute a gate electrode 62, and drain contact electrode 42 and drain wire 47 constitute a drain electrode 63. Furthermore, a passivation film 64 is formed to cover upper surfaces of source electrode 61, gate electrode 62, drain electrode 63, and oxide film 38. This passivation film 64 is made, for example, of SiO₂ and has a function to electrically isolate source electrode 61, gate electrode 62 and drain electrode 63 from the outside and to protect JFET 3.

An operation of JFET 3 will now be described. In n type layer 33, a region sandwiched between first p type region 36 and second n type region 37, a region (drift region) sandwiched between the foregoing sandwiched region and drift layer 32, and a region (channel region) sandwiched between first p type region 36 and drift layer 32 are not depleted when gate electrode 62 has a voltage of 0 V. Hence, first n type region 35 and second n type region 37 are connected to each other via n type layer 33. Therefore, electrons migrate from first n type region 35 toward second n type region 37, whereby a current flows.

Meanwhile, when a negative voltage is applied to gate contact electrode 41 and is increased, depletion of the channel region and the drift region described above proceeds to electrically disconnect first n type region 35 and second n type region 37 from each other. Therefore, electrons cannot migrate from first n type region 35 toward second n type region 37, whereby no current flows.

The following describes a method for manufacturing JFET 3.

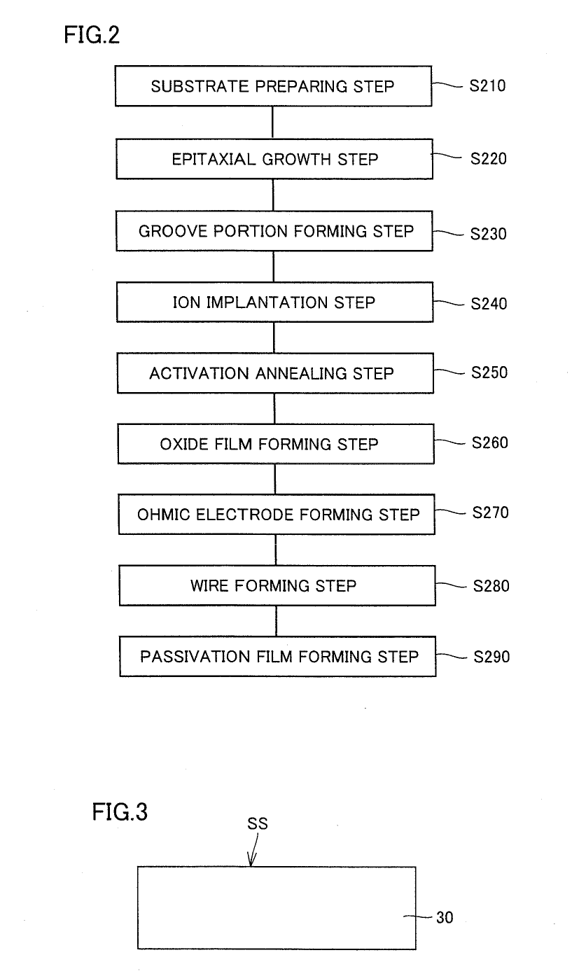

Referring to FIG. 2 and FIG. 3, as a step S210, a substrate 30 is prepared first.

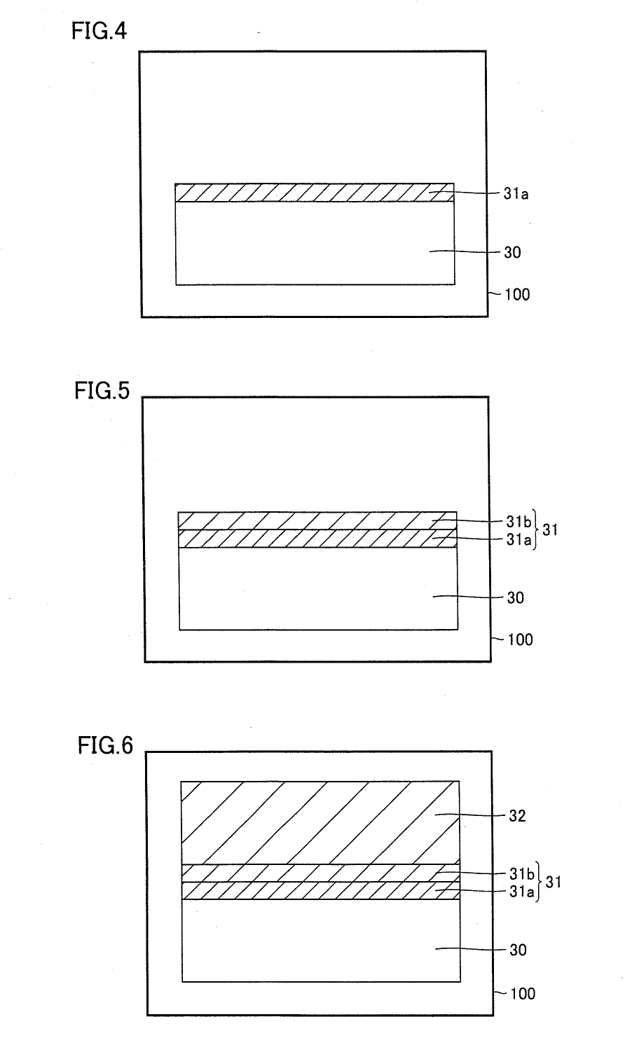

Next, as a step S220 (FIG. 2), an epitaxial growth step described below is performed in a chamber 100 by means of a chemical vapor deposition (CVD) method in which a process gas is supplied onto substrate 30 (FIG. 4). The process gas used in the CVD includes: a carrier gas; a material gas for forming silicon carbide; and an impurity gas for adding an impurity. The carrier gas is, for example, hydrogen (H₂) gas. The material gas is, for example, silane (SiH₄) gas and propane (C₃H₈) gas.

Referring to FIG. 4, a setting temperature of substrate 30 is set at a predetermined value. The setting temperature thereof is, for example, 1550° C. In this way, substrate 30 starts to be heated. After substrate 30 has started to be heated, first layer 31a is deposited. In doing so, trimethylaluminum (TMA) gas is used as the impurity gas to provide first layer 31a with p type conductivity.

Referring to FIG. 5, with an amount of supply of the TMA gas being reduced after forming first layer 31a, second layer 31b starts to be deposited on first layer 31a. In this way, buffer layer 31 constituted by first layer 31a and second layer 31b is formed.

Referring to FIG. 6, after forming buffer layer 31, the amount of supply of the TMA gas is further reduced, thereby depositing drift layer 32 on buffer layer 31. Next, the supply of the TMA gas is stopped. Preferably, throughout both the step of depositing buffer layer 31 and the step of depositing drift layer 32, the setting temperature of substrate 30 is maintained constant. Further, preferably, throughout both the step of depositing buffer layer 31 and the step of depositing drift layer 32, a total pressure in chamber 100 is maintained constant.

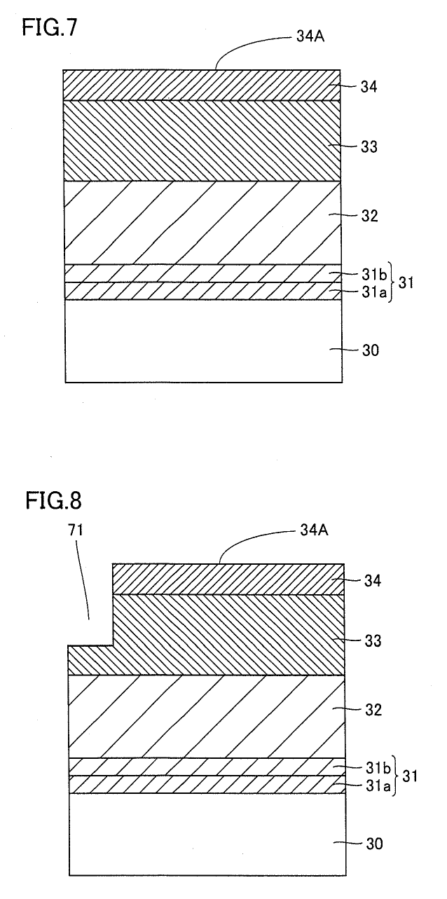

Referring to FIG. 7, instead of the TMA gas, an impurity gas for forming an n type impurity is included in the process gas. Accordingly, n type layer 33 is deposited on drift layer 32. As the impurity gas, for example, nitrogen (N₂) or ammonia (NH₃) can be used. Next, the impurity gas is replaced with an impurity gas for forming a p type impurity. Accordingly, p type layer 34 is deposited on n type layer 33.

In this way, the epitaxial growth step as step S210 (FIG. 2) is performed.

Referring next to FIG. 2, in a step S230, a groove portion forming step is performed. Specifically, as shown in FIG. 8, groove portion 71 is foamed to extend from upper surface 34A of p type layer 34 through p type layer 34 to reach or come into n type layer 33. Groove portion 71 is formed by forming, on upper surface 34A of p type layer 34, a mask layer having an opening for a desired position where groove portion 71 is to be formed and thereafter performing dry-etching using SF₆ gas, for example.

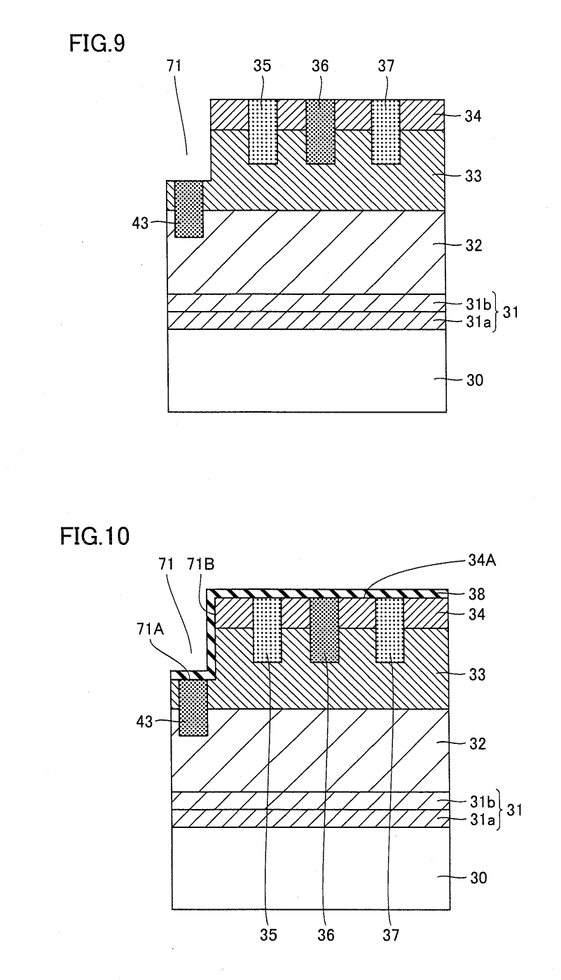

Referring next to FIG. 2, in a step S240, an ion implantation step is performed. Specifically, referring to FIG. 9, initially, an oxide film composed of SiO₂ is formed on upper surface 34A of p type layer 34 and on the bottom wall of groove portion 71, for example, with CVD. Then, after a resist is applied onto the oxide film, exposure and development are performed to thereby form a resist film having openings in regions in conformity with desired shapes of first n type region 35 and second n type region 37. Using this resist film as a mask, the oxide film is partially removed, for example, through RIE (Reactive Ion Etching), whereby a mask layer formed of the oxide film having an opening pattern is formed on upper surface 34A of p type layer 34. Thereafter, the resist film above is removed, and using this mask layer as a mask, ions are implanted into n type layer 33 and p type layer 34. A type of ions to be implanted is, for example, P, N, or the like. First n type region 35 and second n type region 37 reaching or coming into n type layer 33 through p type layer 34 are thus formed.

In addition, after the mask layer used to form first n type region 35 and second n type region 37 is removed, a mask layer having openings in regions in conformity with desired shapes of first p type region 36 and second p type region 43 is formed on upper surface 34A of p type layer 34 and on the bottom wall of groove portion 71 in accordance with a similar procedure. Then, using this mask layer as a mask, ions are implanted into drift layer 32, n type layer 33 and second p type layer 34. A type of ions to be implanted is, for example, Al, B, or the like. First p type region 36 reaching or coming into n type layer 33 through p type layer 34 and second p type region 43 reaching or coming into drift layer 32 through n type layer 33 from bottom wall 71A of groove portion 71 are thus formed.

Referring next to FIG. 2, as a step S250, an activation annealing step is performed. For example, heating is performed at 1700° C. in an inert gas atmosphere such as argon for 30 minutes. Thus, the impurities such as P and Al introduced in step S240 are activated to function as the n type impurity and the p type impurity.

Referring next to FIG. 2, in a step S260, an oxide film forming step is performed. Specifically, referring to FIG. 10, for example, thermal oxidation treatment is performed to heat them in an oxygen atmosphere at approximately 1300° C. for approximately 90 minutes, thereby forming oxide film 38 (field oxide film) serving as an insulating film that covers upper surface 34A of p type layer 34 as well as bottom wall 71A and side wall 71B of groove portion 71. Oxide film 38 has a thickness, for example, of approximately 0.1 μm.

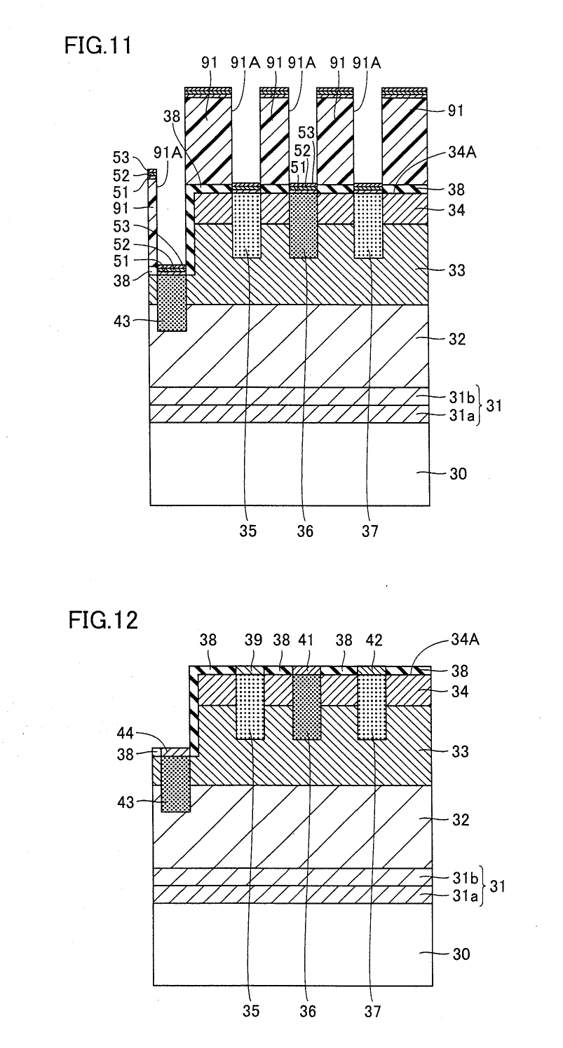

Referring next to FIG. 2, in a step S270, an ohmic electrode forming step is performed. Specifically, referring to FIG. 11, initially, after a resist is applied onto oxide film 38, exposure and development are performed to thereby form resist film 91 having opening 91A in conformity with regions where source contact electrode 39, gate contact electrode 41, drain contact electrode 42, and potential holding contact electrode 44 (see FIG. 1) are to be formed. Then, using resist film 91 as a mask, oxide film 38 is partially removed, for example, through RIE. Thereafter, a Ti film 51 composed of Ti, an Al film 52 composed of Al, and a Si film 53 composed of Si are formed on resist film 91 and in a region exposed through resist film 91. In addition, as a result of removal of resist film 91, Ti film 51, Al film 52, and Si film 53 on resist film 91 are removed (lifted off), so that Ti film 51, Al film 52 and Si film 53 remain in contact with first n type region 35, first p type region 36, second n type region 37, and second p type region 43.

Referring to FIG. 12, alloying treatment is performed to heat them to a temperature not lower than 550° C. and not higher than 1200° C., preferably not lower than 900° C. and not higher than 1100° C., for example 1000° C., in an atmosphere of an inert gas such as Ar for a time period not longer than 10 minutes, for example, 2 minutes. Thus, Ti, Al and Si contained in Ti film 51, Al film 52 and Si film 53 respectively as well as Si and C contained in n type layer 33 or p type layer 34 are alloyed. As a result, source contact electrode 39, gate contact electrode 41, drain contact electrode 42, and potential holding contact electrode 44 serving as the ohmic contact electrodes are formed in contact with upper surfaces of first n type region 35, first p type region 36, second n type region 37, and second p type region 43, respectively. Step S270 is completed in the procedure above.

Referring next to FIG. 2, in a step S280, a wire forming step is performed. Specifically, referring to FIG. 1, source wire 45, gate wire 46 and drain wire 47 are respectively formed in contact with the upper surfaces of source contact electrode 39, gate contact electrode 41, and drain contact electrode 42. Source wire 45, gate wire 46, and drain wire 47 can be formed, for example, by forming a resist layer having openings for desired regions where source wire 45, gate wire 46 and drain wire 47 are to be formed, vapor-depositing Al, and thereafter removing (lifting off) Al on the resist layer together with the resist layer.

Referring next to FIG. 2, in a step S290, a passivation film forming step is performed. Specifically, passivation film 64 composed, for example, of SiO₂ is formed to cover the upper surfaces of source electrode 61, gate electrode 62, drain electrode 63, and oxide film 38. This passivation film 64 can be formed, for example, with CVD.

In this way, JFET 3 (FIG. 1) is obtained.

According to the present embodiment, the thickness of buffer layer 31 is greater than 1 μm. Hence, as compared with the case where buffer layer 31 has a thickness equal to or smaller than 1 μm, a longer time elapses from the start of heating of substrate 30 in depositing buffer layer 31. In this way, the temperature of substrate 30 is more stabilized at the point of starting the deposition of drift layer 32. Thus, substrate 30 can attain the temperature with improved precision in the step of depositing buffer layer 31. Hence, there can be obtained drift layer 32 having a desired impurity concentration. When buffer layer 31 has a thickness greater than 2 μm, precision can be improved more sufficiently.

During a period of time until the temperature of substrate 30 is stabilized, buffer layer 31 is deposited rather than nothing being performed while waiting for time to pass. Thus, while growing the surface of substrate 30, one can wait until the temperature of substrate 30 is stabilized. Thus, unlike the case of just waiting for the temperature to be stabilized, the surface thereof can be avoided from being carbonized due to desorption of Si atoms. Accordingly, crystallinity in the surface of buffer layer 31 is improved, which leads to improved crystallinity in drift layer 32 to be deposited thereon.

Further, because buffer layer 31 has a thickness smaller than 7 μm, time required for the deposition of buffer layer 31 does not become too long. Preferably, throughout the step of depositing buffer layer 31 and the step of depositing drift layer 32, the setting temperature of substrate 30 is maintained constant. Accordingly, in the step of depositing drift layer 32, substrate 30 can attain the temperature with improved precision. More preferably, throughout the step of depositing buffer layer 31 and the step of depositing drift layer 32, a total pressure in chamber 100 is maintained constant. Accordingly, the total pressure in chamber 100 is stabilized when starting film the formation of drift layer 32.

### Example

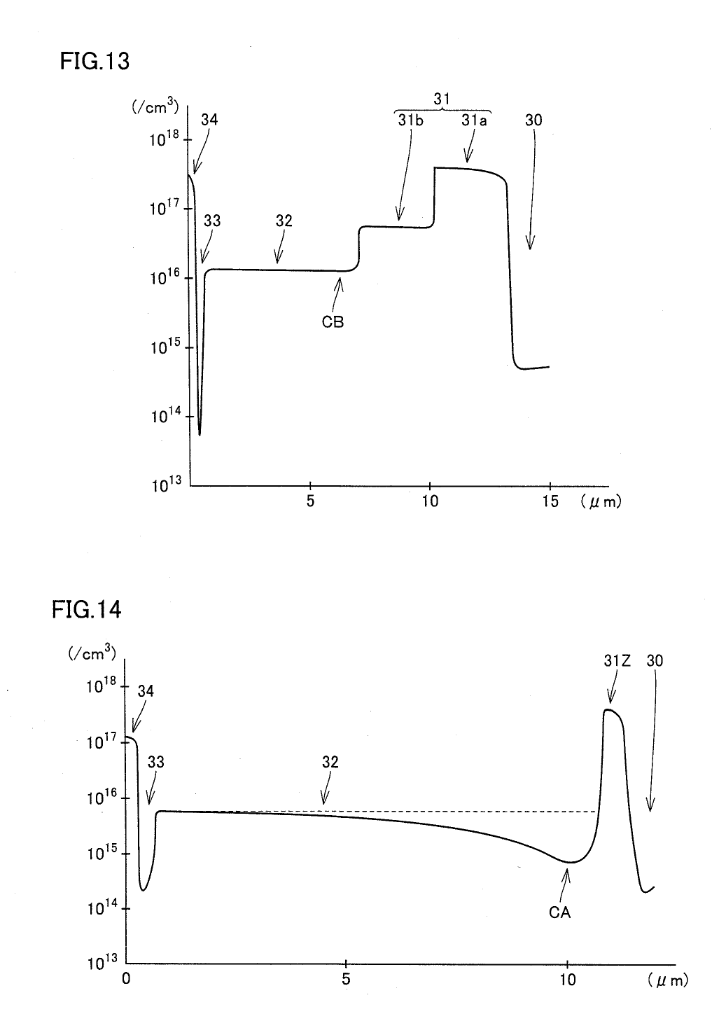

Referring to FIG. 13, a device including buffer layer 31 having a thickness of 6 μm was manufactured as an example of the JFET (FIG. 1) of the present embodiment. When depositing buffer layer 31 with a thickness of 6 μm, concentration of Al serving as the conductive impurity in drift layer 32 was substantially constant. In particular, the concentration of Al was substantially constant in a region CB near buffer layer 31.

Referring to FIG. 14, when depositing a buffer layer 31Z having a thickness of 0.5 μm as a comparative example, the concentration of Al was smaller at a deeper location in drift layer 32. In particular, the concentration of Al was noticeably smaller than a desired value (value indicated by a broken line in the figure) particularly in a region CA close to buffer layer 31Z.

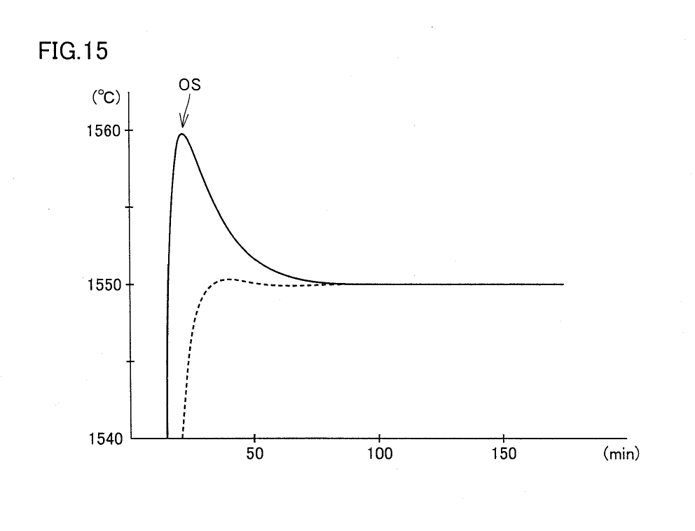

Referring to FIG. 15, an actual temperature of substrate 30 was measured with the setting temperature of substrate 30 being at 1550° C. As a result, the temperature was increased involving an overshoot OS as indicated by a solid line in the figure, unlike ideal temperature increase indicated by a broken line in the figure. The above-described decreased impurity concentration in region CA (FIG. 14) is considered to result from this overshoot OS. Specifically, it is considered that the impurity concentration became smaller because the temperature of substrate 30 was too high.

In order to address this, buffer layer 31 (FIG. 13) thick in thickness in the present example was formed. In this case, even if overshoot OS (FIG. 15) takes place, overshoot OS can be eliminated during the deposition of buffer layer 31 because a long time elapses in depositing buffer layer 31. Accordingly, the impurity concentration of drift layer 32 can be restrained from being decreased due to overshoot OS.

Further, in the configuration of the present embodiment, the p type and the n type may be replaced with each other. In this case, nitrogen can be used as the conductive impurity for each of the buffer layer and the drift layer, for example. Nitrogen can be added into silicon carbide using, for example, nitrogen or ammonia as an impurity gas used for the CVD.

In the description above, the JFET has been illustrated but the silicon carbide semiconductor device may be of other type, such as a MISFET (Metal Insulator Semiconductor Field Effect Transistor) like a MOSFET (Metal Oxide Semiconductor Field Effect Transistor), an IGBT (Insulated Gate Bipolar Transistor), or a diode.

Although the present invention has been described and illustrated in detail, it is clearly understood that the same is by way of illustration and example only and is not to be taken by way of limitation, the scope of the present invention being interpreted by the terms of the appended claims.

1. A silicon carbide semiconductor device comprising:
a substrate;
a buffer layer provided on said substrate, having one conductivity type, made of silicon carbide containing an impurity, and having a thickness larger than 1 μm and smaller than 7 μm; and
a drift layer provided on said buffer layer, having said one conductivity type, and made of silicon carbide having an impurity concentration smaller than that of said buffer layer,
said buffer layer including a first layer provided on said substrate, and a second layer provided on said first layer and having an impurity concentration smaller than that of said first layer and greater than that of said drift layer.

2. The silicon carbide semiconductor device according to claim 1, wherein said buffer layer has an impurity concentration larger than an impurity concentration obtained by multiplying that of said drift layer by 2 and smaller than an impurity concentration obtained by multiplying that of said drift layer by 100.

3. The silicon carbide semiconductor device according to claim 1, wherein the impurity contained in each of said buffer layer and said drift layer includes at least one of aluminum and nitrogen.

4. (canceled)

5. The silicon carbide semiconductor device according to claim 1, wherein the impurity concentration of said first layer is greater than 3×10¹⁶ cm⁻³.

6.-9. (canceled)
